(19) United States
(12) Patent Application Publication
(10) Pub. No.: US 2025/0221284 A1
(43) Pub. Date: Jul. 3, 2025

(54) DISPLAY DEVICE AND METHOD OF FABRICATING THE SAME

(71) Applicant: Samsung Display Co., Ltd., Yongin-Si (KR)

(72) Inventors: Oh June KWON, Yongin-si (KR); Seung Yong SONG, Yongin-si (KR); Jeong Seok LEE, Yongin-si (KR)

(21) Appl. No.: 18/827,877

(22) Filed: Sep. 9, 2024

(30) Foreign Application Priority Data
Jan. 2, 2024 (KR) 10-2024-0000361

(51) Int. Cl. H10K 59/80; H10K 59/12

(52) U.S. Cl. CPC H10K 59/8792; H10K 59/1201; H10K 59/873

(57) ABSTRACT

Provided are display device and method of fabricating the same. A display device comprises a display panel having a first surface and a second surface; a light-blocking layer having a third surface and a fourth surface, the fourth surface facing the first surface of the display panel, the light-blocking layer comprising a recess portion on the third surface and a non-recess portion around the recess portion, and containing a material that selectively blocks light; a light-transmitting layer located on the light-blocking layer; a recess cover disposed between the recess portion and the light-transmitting layer; and an infrared sensor located on the light-transmitting layer and the recess cover, wherein the light-blocking layer blocks light having wavelengths in visible range and transmits light having wavelengths in infrared range.

This application claims priority from Korean Patent Application No. 10-2024-0000361 filed on Jan. 2, 2024 in the Korean Intellectual Property Office, the disclosure of which is incorporated herein by reference in its entirety.

### BACKGROUND

### 1. Field of the Disclosure

The present disclosure relates to a display device and a method of fabricating the same.

### 2. Description of the Related Art

Driven by the evolution of information-oriented society, demands for display devices are ever increasing. For example, display devices are being employed by a variety of electronic devices such as smart phones, digital cameras, laptop computers, navigation devices, and smart televisions.

Among such display devices, different types of display devices such as liquid-crystal display (LCD) devices and organic light-emitting display (OLED) devices are currently used. Among them, an organic light-emitting display device displays images by using an organic light-emitting element that emits light as electrons and holes recombine. Such an organic light-emitting display device includes a plurality of transistors for providing a driving current to the organic light-emitting element.

Such display devices have a variety of features and may include an optical sensor such as a fingerprint recognition sensor, an iris recognition sensor and a proximity sensor.

The optical sensor may be an infrared optical sensor. The infrared optical sensor may include a light-emitting part that emits infrared light and a sensor that receives the infrared ray, and may perform a sensing function by measuring the time that it takes for the emitted infrared ray to be received by the sensor.

In installing such an infrared sensor, a hole is formed in front of the infrared sensor and the infrared sensor is placed in this hole to avoid compromising the sensing function. Unfortunately, this arrangement may result in the infrared sensor being visible to a user through the hole in an outdoor or lighting environment. The infrared sensor may be directly exposed to the user, causing visual discomfort to the user. In addition, the aesthetics of the display device may deteriorate.

In addition, an additional process to form the hole for the infrared sensor is required, and thus there may be assembly errors in a subsequent assembly process due to the hole for the infrared sensor.

### SUMMARY

Aspects of the present disclosure provide a display device that can improve the aesthetics, simplify the fabrication process and prevent assembly errors caused by presence of a hole, and a method of fabricating such display device.

Aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprising a display panel having a first surface and a second surface; a light-blocking layer having a third surface and a fourth surface, the fourth surface facing the first surface of the display panel, the light-blocking layer comprising a recess portion on the third surface and a non-recess portion around the recess portion, and containing a material that selectively blocks light; a light-transmitting layer located on the light-blocking layer; a recess cover disposed between the recess portion and the light-transmitting layer; and an infrared sensor located on the light-transmitting layer and the recess cover, wherein the light-blocking layer blocks light having wavelengths in visible range and transmits light having wavelengths in infrared range.

In an embodiment, the light-blocking layer may comprise a light-blocking pigment that absorbs visible light and transmits infrared light, and wherein the light-blocking pigment comprises at least one of lactam black, perylene black, and aniline black.

In an embodiment, the light-blocking layer may comprise at least one of a urethane resin and an acrylic resin.

In an embodiment, the recess portion may comprise a concave groove having a rectangular cross-section or a semi-elliptical cross-section.

In an embodiment, a thickness of the recess portion may be smaller than a thickness of the non-recess portion, and wherein a distance between an interface where the recess cover contacts the light-blocking layer and a fifth surface of the light-transmitting layer is greater than a thickness of the light-transmitting layer in contact with the non-recess portion.

In an embodiment, the light-transmitting layer may comprise a thermo-curable resin or a photo-curable resin.

In an embodiment, the recess cover may be integrated with the light transmitting layer.

In an embodiment, the display device may further comprise a camera disposed adjacent to the infrared sensor; and an opening extending through the display panel and optically coupling the camera to outside.

In an embodiment, the display panel may comprise a display area and a non-display area around the display area, and wherein the opening is located in the display area.

In an embodiment, the display device may further comprise a polarizer located on a second surface of the display panel, wherein the opening extends through the polarizer, the display panel, the light-blocking layer, and the light-transmitting layer in the display area.

In an embodiment, the display device may further comprise a window located on the polarizer.

According to an aspect of the present disclosure, there is provided a method of fabricating a display device, the method comprise preparing a display panel having a first surface and a second surface; disposing a light-blocking layer on the first surface, the light-blocking layer having a third surface and a fourth surface, the fourth surface of the light-blocking layer facing the first surface of the display panel, the light-blocking layer comprising a recess portion on the third surface and a non-recess around the recess portion, and containing a material that selectively blocks light; disposing a light-transmitting layer comprising a recess cover that fills the recess portion on the light-blocking layer; and disposing an infrared sensor on the light-transmitting layer at a position in line with the recess cover.

In an embodiment, the disposing of the light-blocking layer may comprise forming the light-blocking layer on the first surface; and forming the recess portion and the non-recess portion by patterning the third surface of the light-blocking layer to form a concave groove, the recess portion comprising the concave groove on the third surface.

In an embodiment, the forming the recess portion may comprise etching a portion of the light-blocking layer via a photolithography process.

In an embodiment, the disposing of the light-blocking layer may comprise forming the recess portion and the non-recess portion by inkjet printing.

In an embodiment, the disposing of the light-transmitting layer may comprise filling the recess portion of the light-blocking layer with the recess cover and simultaneously forming the light-transmitting layer on a surface of the light-blocking layer.

In an embodiment, the disposing of the light-transmitting layer may comprise forming the light-transmitting layer with a thermo-curable resin or a photo-curing resin, wherein the disposing the infrared sensor may comprise attaching the infrared sensor on the light-transmitting layer formed of the thermo-curable resin or the photo-curable resin, and wherein the method may further comprise after disposing the infrared sensor, curing the light-transmitting layer with light or heat.

In an embodiment, the disposing of the light-transmitting layer may comprise forming the light-transmitting layer with a thermo-curable resin or a photo-curing resin; curing the light-transmitting layer with light or heat, forming an adhesive layer on the cured light-transmitting layer, and wherein the disposing the infrared sensor comprises attaching the infrared sensor on the adhesive layer.

In an embodiment, the disposing of the light-transmitting layer may comprise forming the light-transmitting layer with a thermo-curable resin or a photo-curing resin; and curing the light-transmitting layer with light or heat, wherein the disposing the infrared sensor may comprise forming an adhesive layer on the infrared sensor; and attaching the infrared sensor to the light-transmitting layer with the adhesive layer formed on the infrared sensor.

In an embodiment, the display panel may comprise a display area and a non-display area around the display area, and wherein the method may further comprise disposing a camera in the display area adjacent to the infrared sensor; disposing a polarizer on a second surface of the display panel; and forming an opening that extends through the polarizer, the display panel, the light-blocking layer and the light-transmitting layer in the display area and optically couples the camera to an outside.

According to an embodiment of the present disclosure, the aesthetics of a display device can be improved, the fabrication process can be simplified, and assembly errors due to a hole can be prevented.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to an exemplary embodiment of the present disclosure.

FIG. 2 is a view showing the front of the display device shown in FIG. 1.

FIG. 3 is a cross-sectional view schematically showing a structure of a display panel of the display device shown in FIG. 1.

FIG. 4 is an enlarged cross-sectional view of a stack structure of the display panel of FIG. 3.

FIG. 5 is a plan view of the display panel of the display device shown in FIG. 1.

FIG. 6 is a cross-sectional view taken along line X1-X1′ of FIG. 2.

FIG. 7 is an enlarged cross-sectional view of the area where a recess portion and a recess cover of FIG. 6 are formed.

FIG. 8 is an enlarged cross-sectional view according to an embodiment different from that of FIG. 7.

FIG. 9 is a flowchart for illustrating a method for fabricating a display device according to an embodiment of the present disclosure.

FIGS. 10 to 14 are cross-sectional views showing processing steps for illustrating the processes of forming the light-blocking layer and the light-transmitting layer in the method of FIG. 9.

### DETAILED DESCRIPTION OF THE EMBODIMENTS

The present disclosure will now be described more fully hereinafter with reference to the accompanying drawings, in which preferred embodiments are shown. This invention may, however, be embodied in different forms and should not be construed as limited to the embodiments set forth herein. Rather, these embodiments are provided so that this disclosure will be thorough and complete, and will fully convey the scope of the disclosure to those skilled in the art. The present inventive concept is defined only by the scope of the claims. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. Likewise, those referred to as “below,” “left,” and “right” include cases where they are directly adjacent to other elements or cases where another layer or other material is interposed.

It will be understood that, although the terms “first,” “second,” etc. may be used herein to describe various elements, these elements should not be limited to any order or priority by these terms. These terms are only used to distinguish one element from another element. For instance, a first element discussed below could be termed a second element without departing from the teachings of the present invention. Similarly, the second element could also be termed the first element.

Hereinafter, exemplary embodiments of the present disclosure will be described in detail with reference to the accompanying drawings.

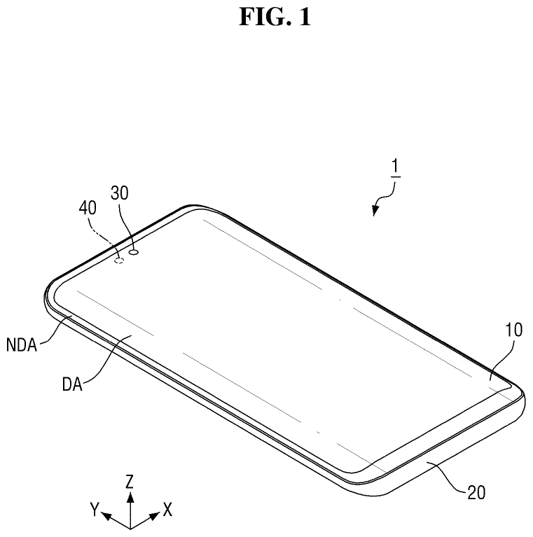

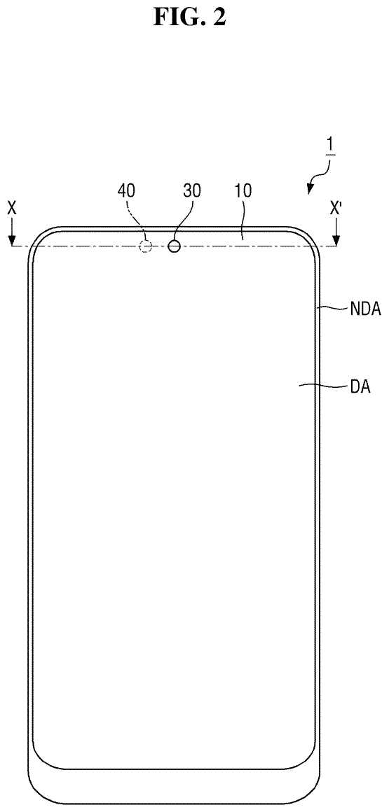

FIG. 1 is a perspective view of a display device according to an embodiment of the present disclosure. FIG. 2 is a view showing the front of the display device shown in FIG. 1.

The display device 1 may be applied to a portable terminal, etc. The portable terminal may include a tablet PC, a smart phone, a personal digital assistant (PDA), a portable multimedia player (PMP), a game device, a wristwatch type electronic device, and the like. It is, however, to be understood that the type of the display device 1 is not limited to those listed above. For example, according to other exemplary embodiments of the present disclosure, the display device 1 may be used in a large electronic device such as a television and an electric board, a small and medium electronic device such as a personal computer, a laptop computer, a vehicle navigation device and a camera.

Referring to FIG. 1, the display device 1 includes a window 10 and a bottom cover 20 that form the exterior of the display device 1.

The window 10 forms the upper exterior of the display device 1 and may be formed of transparent glass or various transparent plastic resins. For example, polyimide (PI) or polyethylene terephthalate (PET) film may be used, but the present disclosure is not limited thereto. Any of a variety of materials that have sufficient transmittance to transmit light may be applied to the window 10.

The bottom cover 20 forms the lower exterior of the display device 1 and may be made of plastic and/or metal.

The display device 1 includes a display panel 100, which will be described later, for displaying images. It may include a display area DA where images may be displayed and a non-display area NDA where no image is displayed.

The non-display area NDA may be located around the display area DA, and the non-display area NDA may surround the display area DA.

The display area DA is defined as an area for displaying images. The shape of the display area DA may be a rectangle or a rectangle with rounded corners when viewed from the top. It is, however, to be understood that the present disclosure is not limited thereto. The shape of the display area DA is not limited thereto, and it may have other shapes such as a circle and an ellipse.

Referring to FIG. 2, the display area DA may include a camera 30 and an infrared (IR) sensor 40 located at an upper portion adjacent to the non-display area NDA when viewed from the front.

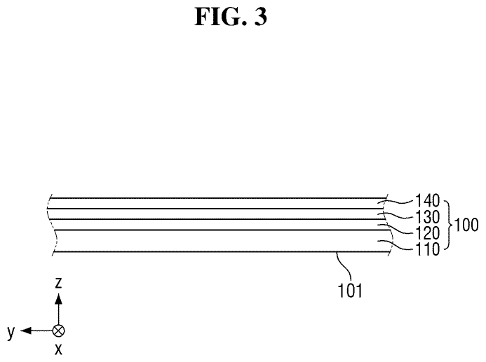

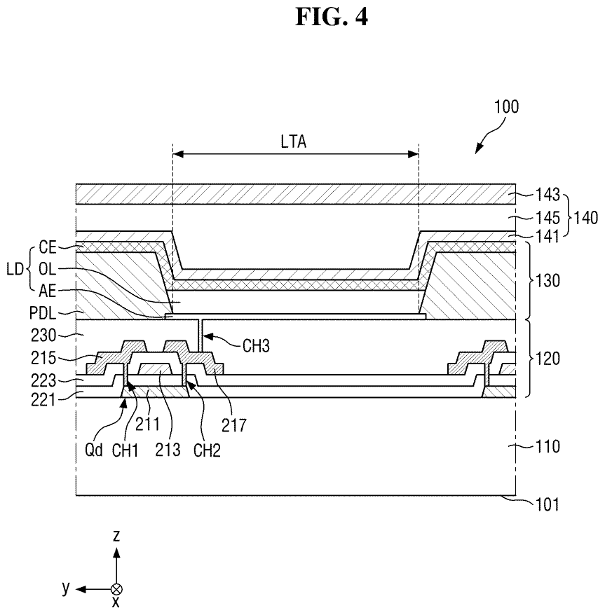

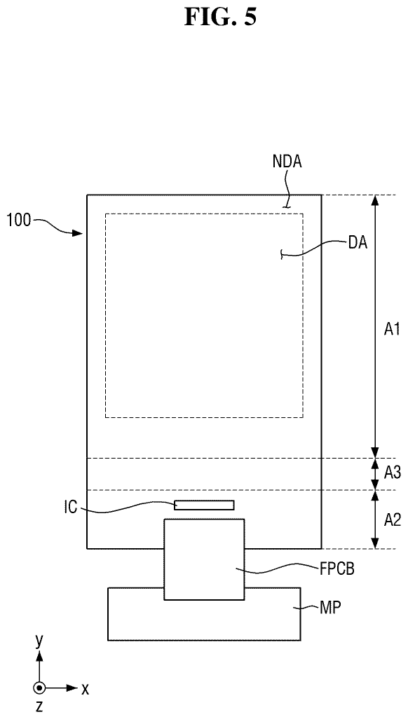

FIG. 3 is a cross-sectional view schematically showing a structure of a display panel of the display device shown in FIG. 1. FIG. 4 is an enlarged cross-sectional view of a stack structure of the display panel of FIG. 3. FIG. 5 is a plan view of the display panel of the display device shown in FIG. 1. FIG. 5 shows the display panel 100 before it is bent or folded.

The display panel 100 may be a display panel 100 including a self-luminous element. In an exemplary embodiment, the self-luminous element may include at least one of an organic light-emitting diode, a quantum dot light-emitting diode, and an inorganic-based micro light-emitting diode (e.g., Micro LED), an inorganic-based nano light-emitting diode (e.g., nano LED). In the following description, it is assumed that the self-luminous element is an organic light-emitting element for convenience of illustration. A detailed description of each of the elements of the display panel 100 will be described later.

Referring to FIG. 3, the display panel 100 may include a base substrate 110, a driving layer 120, an organic light-emitting element layer 130, and an encapsulation layer 140.

The base substrate 110 provides a lower surface 101, which is a first surface of the display panel 100. The base substrate 110 may be a flexible substrate and may be made of a flexible polymer material. For example, the base substrate 110 may be made of a plastic with excellent heat resistance and durability, such as polyethylene ether phthalate, polyethylene naphthalate, polycarbonate, polyarylate, polyetherimide, polyethersulfone, and polyimide.

The driving layer 120 includes elements for providing signals to the organic light-emitting element layer 130. The driving layer 120 may include a variety of signal lines, e.g., a scan line (not shown), a data line (not shown), a power line (not shown), and an emission line (not shown). The driving layer 120 may include a plurality of transistors and a plurality of capacitors. The transistors may include a switching transistor (not shown) and a driving transistor Qd provided for each pixel (not shown).

FIG. 4 shows the driving transistor Qd of the driving layer 120 as an example. The driving transistor Qd includes an active layer 211, a gate electrode 213, a source electrode 215, and a drain electrode 217.

The active layer 211 may be disposed on the base substrate 110. The active layer 211 may include polycrystalline silicon. As another example, the active layer 211 may include monocrystalline silicon, low-temperature polycrystalline silicon, amorphous silicon, or the like. It should be understood, however, that the embodiments of the present disclosure are not limited thereto. The active layer 211 may include an oxide semiconductor.

The driving layer 120 may further include a first insulating film 221 disposed on the active layer 211, and the gate electrode 213 may be located on the first insulating film 221.

The first insulating film 221 may insulate the active layer 211 from the gate electrode 213. The first insulating film 221 may include an inorganic insulating material such as silicon oxide, silicon nitride and silicon oxynitride. The first insulating film 221 may be made up of a single layer or multiple layers of different materials stacked on one another.

The gate electrode 213 may be located on the first insulating film 221 and may overlap with the active layer 211. The gate electrode 213 may include gold (Au), silver (Ag), copper (Cu), nickel (Ni), platinum (Pt), palladium (Pd), aluminum (Al), molybdenum (Mo), etc.

The driving layer 120 may further include a second insulating film 223 located on the gate electrode 213, and the source electrode 215 and the drain electrode 217 may be disposed on the second insulating film 223.

The second insulating film 223 may include at least one of the above-listed materials for the first insulating film 221.

The source electrode 215 and the drain electrode 217 may be connected to the active layer 211 through contact holes CH1 and CH2, respectively, formed in the first insulating film 221 and the second insulating film 223. The source electrode 215 and the drain electrode 217 may be made up of, but is not limited to, a metal multilayer structure of titanium (Ti)/aluminum (Al)/titanium (Ti).

The driving layer 120 may further include a protective film 230 disposed over the source electrode 215 and the drain electrode 217. In some embodiments, the protective film 230 may be a planarization film. For example, the protective film 230 may include an organic insulating material or an inorganic insulating material, or may be implemented as a composite of an organic insulating material and an inorganic insulating material.

Although the structure of the switching transistor is not shown in FIG. 4, the switching transistor (not shown) and the driving transistor Qd may have substantially the same or similar structures. It should be understood, however, that the embodiments of the present disclosure are not limited thereto. The switching transistor (not shown) and the driving transistor Qd may have different structures. For example, the active layer (not shown) of the switching transistor (not shown) and the active layer 211 of the driving transistor Qd may be made of different materials or may be disposed on different layers.

The driving layer 120 may be located not only in the display area DA but also in the non-display area NDA of the display panel 100. Portions of the driving layer 120 which are located in the non-display area NDA, e.g., the portion of the driving layer 120 located in the non-display area NDA of a first area A1 and in a second area A2 and a third area A3 of FIG. 5 may include lines and pads electrically connected to a driver chip IC, and may further include lines and pads electrically connected to a flexible printed circuit board FPCB of FIG. 5.

The organic light-emitting element layer 130 may be a self-luminous element and may include an organic light-emitting element LD. The organic light-emitting element LD may have a top-emission structure and can emit light in the thickness direction or in a third direction (z) of the display panel 100.

The organic light-emitting element (LD) may include a first electrode AE, an organic layer OL, and a second electrode CE.

The first electrode AE is disposed on the protective film 230. The first electrode AE is connected to the drain electrode 217 through a contact hole CH3 formed in the protective film 230. The first electrode AE may be a pixel electrode or an anode. The first electrode AE may be a translucent electrode or a reflective electrode. When the organic light-emitting element LD is implemented as a top-emission type, the first electrode AE may be a reflective electrode. The first electrode AE may include one of: silver (Ag), magnesium (Mg), aluminum (A1), platinum (Pt), palladium (Pd), gold (Au), nickel (Ni), neodymium (Nd), iridium (Ir) and chrome (Cr) or an alloy thereof.

The first electrode AE may be made up of a single layer made of metal oxide or metal, or a multi-layer structure having multiple layers. For example, the first electrode AE may have, but is not limited to, a single-layer structure of indium tin oxide (ITO), silver (Ag) or a mixture of metals (e.g. a mixture of silver (Ag) and magnesium (Mg)), a double-layer structure of indium tin oxide (ITO)/magnesium (Mg) or indium tin oxide (ITO)/magnesium fluoride (MgF), or a triple-layer structure of indium tin oxide (ITO)/silver (Ag)/indium tin oxide (ITO).

The organic layer OL may include an organic emissive layer EML made of a low-molecular organic material or a high-molecular organic material. The organic emissive layer can emit light. Optionally, the organic layer OL may include a hole transport layer (HTL), a hole injection layer (HIL), an electron transport layer (ETL), an electron injection layer (EIL), etc., in addition to the organic emissive layer.

Holes and electrons are injected into the organic emissive layer inside the organic layer OL from the first electrode AE and the second electrode CE, respectively. In the organic emissive layer, excitons are formed by combining holes and electrons, and the excitons fall from the excited state to the ground state so that it is emitted.

The second electrode CE may be disposed on the organic layer OL. The second electrode CE may be a common electrode or a cathode. The second electrode CE may be a transmissive electrode or a semi-transmissive electrode. If the second electrode CE is a translucent electrode, the second electrode CE may include lithium (Li), lithium fluoride (LiF), calcium (Ca), lithium fluoride (LiF)/calcium (Ca), lithium fluoride (LiF)/aluminum (Al), aluminum (Al), magnesium (Mg), barium fluoride (BaF), barium (Ba), silver (Ag), or their compounds or mixtures (e.g., a mixture of silver (Ag) and magnesium ((Mg)).

If the second electrode CE is a transmissive electrode, it may include transparent metal oxide, e.g., indium tin oxide (ITO), indium zinc oxide (IZO), zinc oxide (ZnO) and indium zinc tin oxide (ITZO), and may include molybdenum (Mo), titanium (Ti), silver (Ag), etc.

The organic light-emitting element layer 130 may further include a pixel-defining layer PDL disposed on the protective film 230. The pixel-defining layer PDL may include an opening exposing the first electrode AE and define a light-emitting area LTA when viewed from the top.

The encapsulation layer 140 may be disposed on the organic light-emitting element layer 130. The encapsulation layer 140 can block the organic light-emitting element layer 130 from outside moisture and oxygen.

The encapsulation layer 140 may be formed of a thin-film encapsulation and may include one or more organic films and one or more inorganic films. For example, the encapsulation layer 140 may include a first inorganic film 141 disposed on the second electrode CE, an organic film 145 disposed on the first inorganic film 141, and a second inorganic film 143 disposed on the organic film 145.

The first inorganic film 141 may be disposed on the organic light-emitting element LD and can prevent moisture, oxygen, etc. from permeating into the organic light-emitting element LD. In some embodiments, the first inorganic film 141 includes an inorganic material. As examples of the inorganic material, the first inorganic film 141 may include at least one selected from the group consisting of: silicon oxide (SiOx), silicon nitride (SiNx) and silicon oxynitride (SiONx).

The organic film 141 may be disposed on the first inorganic film 145. The organic film 145 can improve the flatness. The organic film 145 includes an organic material. As examples of the organic material, the organic film 145 may include one selected from the group consisting of: epoxy, acrylate and urethane acrylate.

The second inorganic film 143 may be disposed on the organic film 145. The second inorganic film 143 may perform substantially the same or similar function as the first inorganic film 141 and may be made of a material substantially the same as or similar to the first inorganic film 141. The second inorganic film 143 may completely cover the organic film 145. In some embodiments, the second inorganic film 143 and the first inorganic film 141 may come in contact with each other outside the display area DA to form an inorganic-inorganic junction. By forming the inorganic-inorganic junction, it is possible to effectively prevent moisture, etc. from flowing into the display device 1 from outside of the display device 1.

Although each of the first inorganic film 141, the organic film 145 and the second inorganic film 143 is made up of a single layer in the example shown in FIG. 4, the present disclosure is not limited thereto. For example, at least one of the first inorganic film 141, the organic film 145 and the second inorganic film 143 may be made up of multiple layers.

Referring to FIG. 5, the display panel 100 may include the first area A1 including the display area DA, the second area A2 connected to the driver chip IC, the flexible printed circuit board FPCB and a main circuit board MP, and the third area A3 that is bendable.

The driver chip IC may be disposed at the upper portion of the display panel 100 in the second area A2, and pads connected to the driver chip IC may be disposed.

The driver chip IC may include at least one of drivers including a data driver that applies a data signal to a data line, a gate driver that applies a gate signal to a gate line, and a signal controller that controls the operations of the data driver and the gate driver. The number of driver chips ICs is not limited to the example shown.

One end of the flexible printed circuit board FPCB may be located at an edge of the display panel 100 in the second area A2.

The flexible printed circuit board FPCB may be connected to the pads on the display panel 100 through an anisotropic conductive film or the like. The process of connecting the flexible printed circuit board FPCB to the display panel 100 may include a pressing process of applying pressure to the flexible printed circuit board FPCB.

The main circuit board MP may be electrically connected to the display panel 100 through the flexible printed circuit board FPCB and may send/receive signals to/from the driver chip IC. The main circuit board MP may provide image data, control signals, supply voltage, etc. to the display panel 100 or the flexible circuit board FPCB. The main circuit board MP may include active and passive elements.

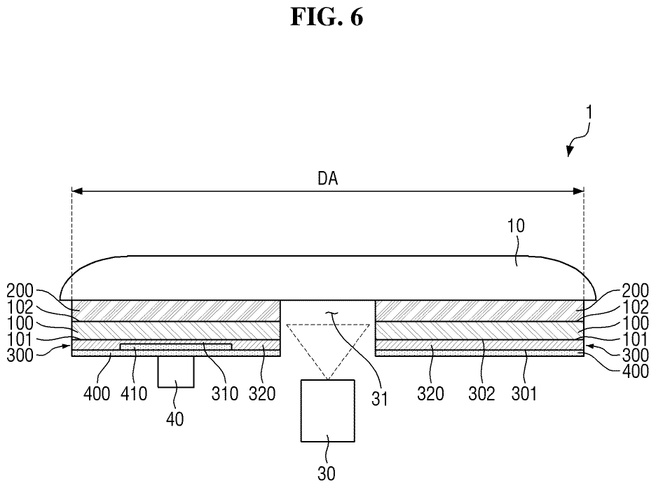

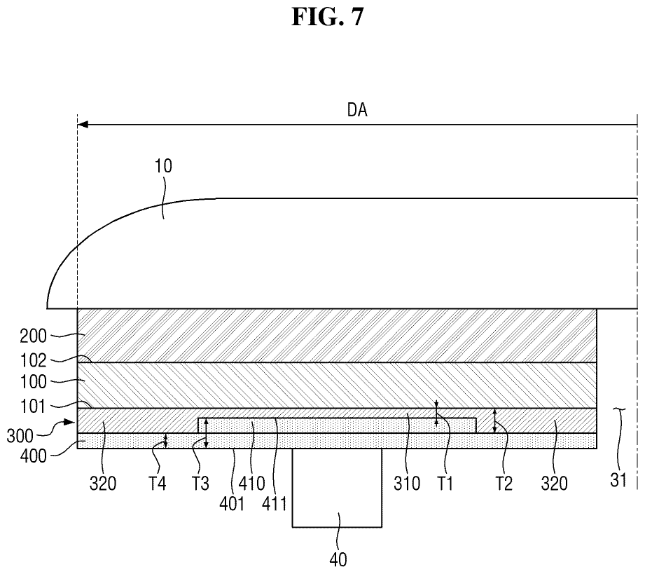

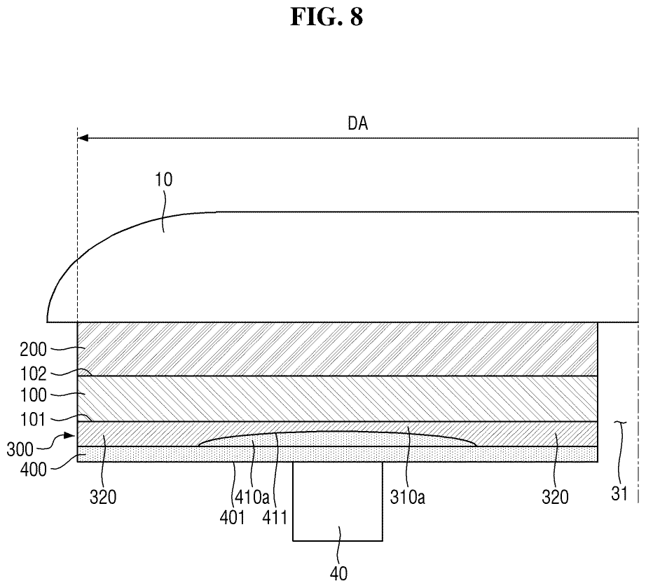

FIG. 6 is a cross-sectional view taken along line X1-X1′ of FIG. 2. FIG. 7 is an enlarged cross-sectional view of the area where a recess portion and a recess cover of FIG. 6 are formed. FIG. 8 is an enlarged cross-sectional view according to an embodiment different from that of FIG. 7.

FIG. 6 is a cross-sectional view of the display area DA of FIG. 2. Referring to FIG. 6, the display device 1 may further include a window 10, a polarizer 200, a light-blocking layer 300, a light transmitting layer 400, a camera 30 and an infrared sensor 40 as well as the display panel 100 including the display area DA.

The window 10 may be disposed over the display panel 100 to cover an upper surface 102, which is a second surface of the display panel 100. The window 10 is disposed over the display panel 100 to cover and protect the upper surface 102 of the display panel 100 while transmitting light output from the display panel 100.

The polarizer 200 may be located between the window 10 and the upper surface 102 of the display panel 100, may display true black to increase the contrast ratio, and may be disposed on the upper surface 102 of the display panel 100 to ensure outdoor visibility.

The camera 30 is located behind the window 10 and is exposed to the outside through the camera hole 31, which is an opening. The camera 30 processes and outputs image frames such as still images and moving images obtained by an image sensor in a camera mode.

The camera hole 31 is formed through the polarizer 200, the display panel 100, the light-blocking layer 300 and the light transmitting layer 400, to expose the camera 30 to the outside.

If the camera hole 31 is located in the display area DA of the display panel 100, it may be formed through the display panel 100. However, if the camera hole 31 is located in the non-display area NDA of the display panel 100, a hole penetrating the panel surface for the camera hole 31 may not be formed in the display panel 100.

The infrared sensor 40 may be disposed adjacent to the camera 30 in the display area DA and may be located on the light-transmitting layer 400. Any infrared sensor well known in the art may be employed as long as it can perform sensing using infrared light.

The infrared sensor 40 may be in contact with the light-transmitting layer 400, or may be spaced apart from the light-transmitting layer 400.

For example, the infrared sensor 40 may be installed in direct contact with the light-transmitting layer 400, or may be installed in the light-transmitting layer 400 by using an adhesive support (not shown) or by forming a separate groove (not shown).

Although the infrared sensor 40 and the camera 30 are located in the display area DA shown in FIG. 6, they may be located in the non-display area NDA.

The light-blocking layer 300 is formed on the entire lower surface 101 of the display panel 100 and is located between the light-transmitting layer 400 and the lower surface 101 of the display panel 100. The light-blocking layer 300 may be formed by applying a coating liquid for a light-blocking layer to the display panel 100, and may be formed, for example, using a method selected from spin coating, dip coating, silk printing and inkjet printing. As an example, it may be desirable to form the light-blocking layer by applying a coating liquid by inkjet printing, but the present disclosure is not limited thereto. The light-blocking layer may have a third surface 301 and a fourth surface 302 that are on opposite sides, wherein the fourth surface 302 contacts the first surface 101 of the display panel.

The light-blocking layer 300 may include a light-blocking material that can selectively absorb light in the visible wavelength range (380 to 780 nm) by absorbing or reflecting it and transmit light in the infrared wavelength range (780 nm or more). For example, it may be desirable for the light-blocking layer 300 to have a transmittance that can transmit light in a wavelength range of 900 nm or more, but the present disclosure is not limited thereto.

The light-blocking material may include at least one organic pigment selected from lactam black, perylene black, and aniline black. It should be understood, however, that the light-blocking material is not limited thereto. Both colored dyes and opaque dyes may be used as long as they can block visible light and transmit infrared light.

For example, the color dye may include synthetic dyes such as an anthraquinone-based synthetic dye, an azo-based synthetic dyes a methine-based synthetic dye, a quinoline-based synthetic dye, a perylene-based synthetic dye, an azine-based synthetic dye and a nigrosine dye with excellent light-blocking properties, or may include an organic dye such as a phthalocyanine-based dye, a dioxazine-based dyes and a perylene-based dye with excellent shielding properties on the visible range.

The light-blocking layer 300 may be formed as a hard layer with greater hardness than the light-transmitting layer 400. In order to provide such hardness, it may be desired to form the light-blocking layer 300 with a urethane resin or an acrylic resin, but the present disclosure is not limited thereto. In addition, as an example, the light-blocking layer 300 may be formed of, but is not limited to, one or more resins selected from polycarbonate, polypropylene and polyethylene.

The light-blocking layer 300 may include a recess portion 310 formed at a position where the infrared sensor 40 is disposed, and a non-recess portion 320 that is the other area than the recess portion 310. The horizontal width of the recess portion 310 may be larger than the horizontal width of the infrared sensor 40.

The recess portion 310 may be located between a recess cover 410, which will be described later, and the lower surface 101 of the display panel 100, and may include a concave groove shape depressed toward the lower surface 101 of the display panel 100.

Referring to FIG. 7, the recess portion 310 may include a concave groove with a rectangular cross-section. As another example, as shown in FIG. 8, a recess portion 310a may include a concave groove with a semi-elliptical cross-section. It should be understood, however, that the embodiments of the present disclosure are not limited thereto. The recess portion may have a variety of shapes.

The recess portion 310 may be formed of the same material as the light-blocking layer 300 including the light-blocking material. Accordingly, the recess portion 310 of the light-blocking layer 300 containing the light-blocking material serves to block the infrared sensor 40, thereby preventing the infrared sensor 40 from being seen by a user. In other words, it can cover the infrared sensor 40 so that it is not directly seen by the user or exposed to the outside.

In an existing display device, an infrared sensor was directly exposed to a user, which may deteriorate the aesthetics and cause visual discomfort to the user. In contrast, according to the embodiment of the present disclosure, the recess portion 310 is provided between the display panel 100 and the infrared sensor 40, so that the infrared sensor 40 is coved and thus is not directly exposed to the user. As a result, visual discomfort to the user can be eliminated and the aesthetics can be improved.

The non-recess portion 320 is the remaining area of the light-blocking layer 300 excluding the recess portion 310, and may contain the same light-blocking material as the light-blocking layer 300.

The non-recess portion 320 may be formed integrally with the recess portion 310 using the same material as the recess portion 310. Alternatively, the non-recess portion 320 and the recess portion 310 may be formed separately, and each of the non-recess portion 320 and the recess portion 310 may be attached to the lower surface 101 of the display panel 100.

The non-recess portion 320 may have a different thickness from the recess portion 310. For example, as shown in FIG. 7, the thickness T1 of the recess portion 310 may be smaller than the thickness T2 of the non-recess portion 320.

As the thickness T1 of the recess portion 310 disposed at the position where the infrared sensor 40 is disposed is smaller than the thickness T2 of the non-recess portion 320, the recess portion 310 transmits infrared light while blocking the shape of the infrared sensor 40, so that it is not seen by the user.

The light-transmitting layer 400 may be located between the light-blocking layer 300 and the infrared sensor 40, and may be formed by applying a coating liquid for the light-transmitting layer to the display panel 100. For example, the light-transmitting layer 400 may be formed using a method selected from spin coating, dip coating, silk printing and inkjet printing. As an example, it may be desirable to form the light-transmitting layer by applying a coating liquid by inkjet printing, but the present disclosure is not limited thereto.

The light-transmitting layer 400 may be formed as a transparent layer or a non-transparent layer, and may be formed in a variety of ways as long as it is made of a material that can transmit light. For example, it is desired to form the light-transmitting layer 400 that transmits light having a wavelength range of 450 to 800 nm, but the present disclosure is not limited thereto.

The light-transmitting layer 400 also has adhesive properties and may couple the infrared sensor 40 with the lower surface 101 of the display panel 100.

As such, the light-transmitting layer 400 may be made of any of a variety of materials as long as it is a material that transmits light and has adhesive properties.

The light-transmitting layer 400 may be formed of, for example, a photo-curable or thermo-curable resin. For example, it may be formed of one or more of: polyester acrylate, epoxy acrylate, urethane acrylate, polyether acrylate, silicone acrylate, cycloaliphatic epoxy resins, glycidyl ether epoxy resins, epoxy acrylate and vinyl ethers.

The light-transmitting layer 400 may be formed as a soft layer with smaller hardness than the light-blocking layer 300. To provide such hardness, it may be formed of, but is not limited to, silicone.

As the light-transmitting layer 400 is formed as the soft layer, it can serve as a protective layer to prevent the display panel 100 from being impacted or damaged by pressing force when the infrared sensor 40 is disposed.

The light-transmitting layer 400 is formed on the surface (e.g., the entire surface) of the light-blocking layer 300, and may include a recess cover 410 for covering the recess portion 310 between the light-transmitting layer 400 and the recess portion 310 of the light-blocking layer 300.

The recess cover 410 fills the recess portion 310 including a concave groove at the position where the infrared sensor 40 is disposed.

The recess cover 410 may be formed as a protrusion that protrudes from the light-transmitting layer 400 toward the recess portion 310, conforming to the shape of the recess portion 310 including the concave groove. As shown in FIG. 7, the recess cover 410 may conform to the recess portion 310 including a concave groove of a rectangular cross-section. As another example, as shown in FIG. 8, the recess cover 410a may conform to the recess portion 310a including a concave groove of a semi-elliptical cross-section. It should be understood, however, that the embodiments of the present disclosure are not limited thereto. The recess portion may have a variety of shapes.

The recess cover 410 may be formed integrally with the light-transmitting layer 400 using the same material as the light-transmitting layer 400, or may be formed separately from the light-transmitting layer 400.

FIG. 7 depicts a thickness T3, which is a distance from an interface 411 where the light-blocking layer 300 contacts the recess cover 410 in the deepest section of the recess portion 310, to the fifth surface 401 of the light-transmitting layer 400. The light-transmitting layer 400 is a surface of the light-transmitting layer 400 on which the infrared sensor 40 is disposed. The thickness T3 may be greater than the thickness T4 of the light-transmitting layer 400 in contact with the non-recess portion 320.

As the thickness T3 at the position where the infrared sensor 40 is installed is larger than the thickness T4 of the light-transmitting layer 400 in contact with the non-recess portion 320, and the recess cover 410 is formed integrally with the light-transmitting layer 400, which is the soft layer, it is possible to prevent the display panel 100 from being impacted or damaged by pressing force applied when the infrared sensor 40 is installed at the position under the recess cover portion 410. In addition, the protective layer can stably support the infrared sensor 40.

As such, according to the embodiment, although underlying structures such as an adhesive layer, a plating layer, a metal layer and a support film are located under the existing display panel, the light-blocking layer 300 and the light-transmitting layer 400 are formed directly under the display panel 100, so that optical functionality and cushioning properties can be provided while eliminating a panel bottom cover. As a result, the overall thickness of the display device 1 can be reduced.

In addition, the recess portion 310 can prevent the infrared sensor 40 from being visible to the outside so that the user cannot see the infrared sensor 40, and can prevent the display panel 100 from being damaged or defective due to external force when installing the infrared sensor 40.

In addition, as the infrared sensor 40 is installed on the light-transmitting layer 400 without a hole, the existing process of forming a hole for the infrared sensor 40 can be omitted, and thus it is possible to simplify the fabrication process. Further, by not forming the hole for the infrared sensor, it is possible to prevent assembly errors from occurring in a subsequent assembly process due to the hole.

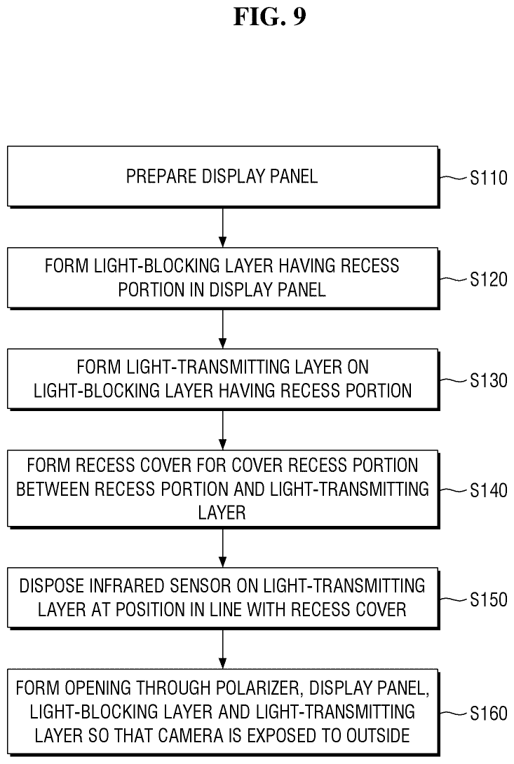

Hereinafter, a method of fabricating a display device 1 according to an embodiment of the present disclosure will be described with reference to FIGS. 9 to 14.

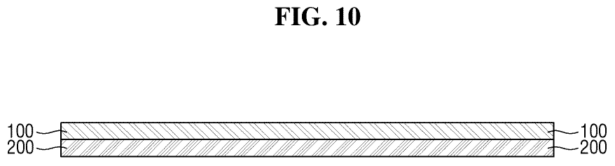

FIG. 9 is a flowchart for illustrating a method for fabricating a display device according to an embodiment of the present disclosure. FIGS. 10 to 14 are cross-sectional views showing processing steps for illustrating the processes of forming the light-blocking layer and the light-transmitting layer in the method of FIG. 9.

Referring to FIG. 9, the method of fabricating the display device 1 may include the following steps:

First, the method may include preparing a display panel 100 (step S110 in FIG. 9).

Referring to FIG. 10, a polarizer 200 and a display panel 100 are stacked on each other, but this is merely illustrative for describing the configuration. The polarizer 200 may be stacked on the display panel 100 after all processes are completed, or the processes may be performed with the polarizer 200 stacked on the display panel 100 as shown in FIG. 10. The order of the process is not limited to that shown in the drawing.

Second, the method may include forming a light-blocking layer 300 having a recess portion 310 on the display panel 100 (step S120 of FIG. 9).

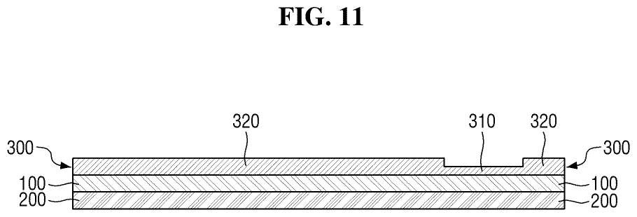

Referring to FIG. 11, by applying a coating liquid for a light-blocking layer onto the display panel 100 by inkjet printing, the light-blocking layer 300 can be formed with a certain area as a recess portion 310 including a concave groove shape and the other area than the recess portion 310 as a non-recess portion 320.

Alternatively, the recess portion 310 may be formed by applying the coating liquid for the light-blocking layer onto the entire surface of the display panel 100 by inkjet printing and then processing a patterning process of etching a certain area using a photolithography process.

Third, the method may include forming a light-transmitting layer 400 on the light-blocking layer 300 including the recess portion 310 (step S130 in FIG. 9).

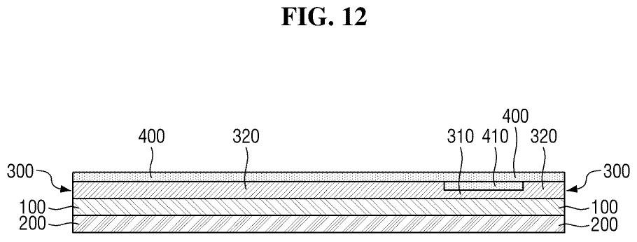

Referring to FIG. 12, the light-transmitting layer 400 may be formed by applying a coating liquid for the light-transmitting layer on the light-blocking layer 300 by inkjet printing or silk printing.

Fourth, the method may include forming a recess cover 410 that covers the recess portion 310 between the recess portion 310 and the light-transmitting layer 400 (step S140 of FIG. 9).

Referring to FIG. 12, when the coating liquid for the light-transmitting layer is applied to the entire surface of the light-blocking layer 300 including the non-recess portion 320 and the recess portion 310 to form the light-transmitting layer 400, the recess portion 310 including the concave groove shape is filled with the coating liquid for the light-transmitting layer, and accordingly the recess cover 410 may be formed together.

As a result, the light-transmitting layer 400 is located on the non-recess portion 320 of the light-blocking layer 300 and on the recess cover 410 that fills the recess portion 310.

Fifth, the method may include disposing an infrared sensor 40 on the light-transmitting layer 400 (step S150 in FIG. 9).

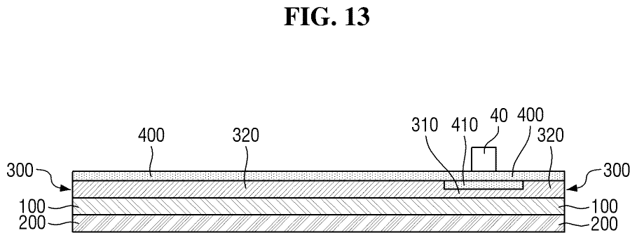

Referring to FIG. 13, the infrared sensor 40 may be disposed on the light-transmitting layer 400 at a position in line with the recess portion 310 and the recess cover 410 that covers the recess portion 310.

If the light-transmitting layer 400 including the recess cover 410 is formed of a photo-curable or thermo-curable resin, the infrared sensor 40 may be formed in the following order:

According to an embodiment, a coating liquid for a light-transmitting layer may be applied on the light-blocking layer 300 to form a light-transmitting layer 400 including a recess cover 410, and then an infrared sensor 40 may be attached thereon. Subsequently, the infrared sensor 40 may be coupled with the light-transmitting layer 400 by curing it with light or heat. During light or heat curing, the infrared sensor 40 can be firmly coupled as the adhesive strength increases.

According to another embodiment, a coating liquid for a light-transmitting layer may be applied on the light-blocking layer 300 to form a light-transmitting layer 400 including a recess cover 410, and then it is cured with light or heat. Subsequently, a separate adhesive layer is formed on the light-transmitting layer 400 and the infrared sensor 40 may be coupled on the separate adhesive layer.

According to yet another embodiment, a coating liquid for a light-transmitting layer may be applied on the light-blocking layer 300 to form a light-transmitting layer 400 including a recess cover 410, and then it is cured with light or heat. Subsequently, a separate adhesive layer is formed on the infrared sensor 40, and the infrared sensor 40 with the adhesive layer is coupled with the light-transmitting layer 400.

The method may include forming a camera hole 31, which is an opening that optically couples a camera 30 to the outside (step S160 in FIG. 9). As used herein, two elements being “optically coupled” indicates that the two elements are visible to each other.

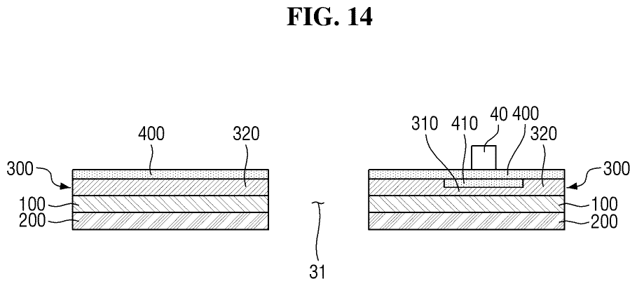

Referring to FIG. 14, a camera hole 31, which is an opening that extends through the light transmitting layer 400, the light-blocking layer 300, the display panel 100 and the polarizer 200, is formed using laser hole processing.

Although the camera hole 31 is formed after all of the layers have been formed in the example shown in FIG. 14, the processing order is not limited by the example, in some cases, the hole may be formed during the process of forming the layers, or the hole may be formed first and then the layers may be stacked.

According to the method of fabricating the display device 1 according to the embodiment, the infrared sensor 40 is not exposed to the user, thereby improving the aesthetics of the display device 1 and simplifying the fabrication process. In addition, it is possible to prevent assembly errors which may occur during a process of forming a separate hole.

In concluding the detailed description, those skilled in the art will appreciate that many variations and modifications can be made to the embodiments without substantially departing from the principles of the present invention. Therefore, the disclosed embodiments are used in a generic and descriptive sense only and not for purposes of limitation. Each component specifically shown in the embodiments of the present disclosure can be implemented by modification, and such modifications and differences related to application should be construed as being included in the scope of the present disclosure defined in the appended claims.

What is claimed is:

1. A display device comprising:
a display panel having a first surface and a second surface;
a light-blocking layer having a third surface and a fourth surface, the fourth surface facing the first surface of the display panel, the light-blocking layer comprising a recess portion on the third surface and a non-recess portion around the recess portion, and containing a material that selectively blocks light;
a light-transmitting layer located on the light-blocking layer;
a recess cover disposed between the recess portion and the light-transmitting layer; and
an infrared sensor located on the light-transmitting layer and the recess cover,
wherein the light-blocking layer blocks light having wavelengths in visible range and transmits light having wavelengths in infrared range.

2. The display device of claim 1, wherein the light-blocking layer comprises a light-blocking pigment that absorbs visible light and transmits infrared light, and
wherein the light-blocking pigment comprises at least one of lactam black, perylene black, and aniline black.

3. The display device of claim 1, wherein the light-blocking layer comprises at least one of a urethane resin and an acrylic resin.

4. The display device of claim 1, wherein the recess portion comprises a having a rectangular cross-section or a semi-elliptical cross-section.

5. The display device of claim 1, wherein a thickness of the recess portion is smaller than a thickness of the non-recess portion, and
wherein a distance between an interface where the recess cover contacts the light-blocking layer and a fifth surface of the light-transmitting layer is greater than a thickness of the light-transmitting layer in contact with the non-recess portion.

6. The display device of claim 1, wherein the light-transmitting layer comprises a thermo-curable resin or a photo-curable resin.

7. The display device of claim 1, wherein the recess cover is integrated with the light transmitting layer.

8. The display device of claim 1, further comprising:
a camera disposed adjacent to the infrared sensor; and
an opening extending through the display panel and optically coupling the camera to outside.

9. The display panel of claim 8, wherein the display panel comprises a display area and a non-display area around the display area, and
wherein the opening is located in the display area.

10. The display device of claim 9, further comprising:
a polarizer located on a second surface of the display panel,
wherein the opening extends through the polarizer, the display panel, the light-blocking layer, and the light-transmitting layer in the display area.

11. The display device of claim 10, further comprising: a window located on the polarizer.

12. A method of fabricating a display device, the method comprising:
preparing a display panel having a first surface and a second surface;
disposing a light-blocking layer on the first surface, the light-blocking layer having a third surface and a fourth surface, the fourth surface of the light-blocking layer facing the first surface of the display panel, the light-blocking layer comprising a recess portion on the third surface and a non-recess portion around the recess portion, and containing a material that selectively blocks light;
disposing a light-transmitting layer comprising a recess cover that fills the recess portion on the light-blocking layer; and
disposing an infrared sensor on the light-transmitting layer at a position in line with the recess cover.

13. The method of claim 12, wherein the disposing of the light-blocking layer comprises:
forming the light-blocking layer on the first surface; and
forming the recess portion and the non-recess portion by patterning the third surface of the light-blocking layer a concave groove, the recess portion comprising the concave groove on the third surface.

14. The method of claim 13, wherein the forming the recess portion comprises: etching a portion of the light-blocking layer via a photolithography process.

15. The method of claim 12, wherein the disposing of the light-blocking layer comprises forming the recess portion and the non-recess portion by inkjet printing.

16. The method of claim 12, wherein the disposing of the light-transmitting layer comprises: filling the recess portion of the light-blocking layer with the recess cover and simultaneously forming the light-transmitting layer on a surface of the light-blocking layer.

17. The method of claim 12, wherein the disposing of the light-transmitting layer comprises forming the light-transmitting layer with a thermo-curable resin or a photo-curing resin,
wherein the disposing the infrared sensor comprises attaching the infrared sensor on the light-transmitting layer formed of the thermo-curable resin or the photo-curable resin, and
wherein the method further comprises:
after disposing the infrared sensor, curing the light-transmitting layer with light or heat.

18. The method of claim 12, wherein the disposing of the light-transmitting layer comprises:
forming the light-transmitting layer with a thermo-curable resin or a photo-curing resin;
curing the light-transmitting layer with light or heat,
forming an adhesive layer on the cured light-transmitting layer, and
wherein the disposing the infrared sensor comprises attaching the infrared sensor on the adhesive layer.

19. The method of claim 12, wherein the disposing of the light-transmitting layer comprises
forming the light-transmitting layer with a thermo-curable resin or a photo-curing resin; and
curing the light-transmitting layer with light or heat,
wherein the disposing the infrared sensor comprises:
forming an adhesive layer on the infrared sensor; and
attaching the infrared sensor to the light-transmitting layer with the adhesive layer formed on the infrared sensor.

20. The method of claim 12, wherein the display panel comprises a display area and a non-display area around the display area, and
wherein the method further comprises:
disposing a camera in the display area adjacent to the infrared sensor;
disposing a polarizer on a second surface of the display panel; and
forming an opening that extends through the polarizer, the display panel, the light-blocking layer and the light-transmitting layer in the display area and optically couples the camera to an outside.
